(19) United States
(12) Patent Application Publication
(10) Pub. No.: US 2024/0213244 A1
(43) Pub. Date: Jun. 27, 2024

(54) VTFET CELL BOUNDARY HAVING AN IN-LINE CONTACT

(71) Applicant: International Business Machines Corporation, Armonk, NY (US)

(72) Inventors: Brent A. Anderson, Jericho, VT (US); Albert M. Chu, Nashua, NH (US); Ruilong Xie, Niskayuna, NY (US); Lawrence A. Clevenger, Saratoga Springs, NY (US); Nicholas Anthony Lanzillo, Wynantskill, NY (US); Reinaldo Vega, Mahopac, NY (US)

(21) Appl. No.: 18/145,059

(22) Filed: Dec. 22, 2022

(51) Int. Cl. H01L 27/092; H01L 21/8238; H01L 23/528; H01L 29/08; H01L 29/417; H01L 29/78

(52) U.S. Cl. CPC H01L 27/092; H01L 21/823871; H01L 21/823885; H01L 23/5286; H01L 29/0847; H01L 29/41741; H01L 29/7827

(57) ABSTRACT

Embodiments of the invention provide a multi-layer integrated circuit (IC) structure that includes a cell having a cell boundary defined by a plurality of transistor-gate pitch (TGP) regions and an in-line contact region. The plurality of TGP regions include a reduced-area TGP region and non-reduced area TGP regions. The reduced-area TGP region is less than each of the non-reduced-area TGP regions. An in-line contact is within the in-line contact region and operable to electrically couple to a source or drain (S/D) region within the in-line contact region.

### BACKGROUND

The present invention generally relates to fabrication methods and resulting structures for integrated circuit (IC) wafers. More specifically, the present invention relates to fabrication methods and resulting structures for providing a cell boundary for a set of vertical transport field effect transistors (VTFETs) having an in-line contact operable to connect to an output from a bottom source or drain (S/D) region or connect to a power supply input to a top S/D region.

ICs are fabricated in a series of stages, including a front-end-of-line (FEOL) stage, a middle-of-line (MOL) stage, and a back-end-of-line (BEOL) stage. The FEOL stage is where device elements (e.g., transistors) are patterned in the substrate/wafer. The MOL stage forms interconnect structures (e.g., lines, wires, metal-filled vias, contacts, and the like) that communicatively couple to active regions (e.g., gate, source, and drain) of the device element. Layers of interconnect structures are formed above these logical and functional layers during the BEOL stage to complete the IC.

Semiconductor devices are typically formed using active regions of a wafer. In an IC having a plurality of metal oxide semiconductor field effect transistors (MOSFETs), each MOSFET has S/D regions that are formed in an active region of a semiconductor layer by incorporating n-type or p-type impurities in the layer of semiconductor material. A conventional MOSFET geometry is a non-planar FET known generally as a VTFET. VTFETs employ semiconductor fins and side-gates that can be contacted outside the active region, resulting in increased device density and some increased performance over lateral/planar devices. In VTFETs, the source-to-drain current flows in a direction that is perpendicular to a major surface of the substrate. For example, in a known VTFET configuration a major substrate surface is horizontal, and a vertical fin extends upward from the substrate surface. The fin forms the channel region of the transistor. A S/D region is situated in electrical contact with the top and bottom ends of the channel region, respectively, while a gate is disposed on one or more of the fin sidewalls.

ICs are designed by placing various cells with different functions. For example, cells can be logic gates, such as an AND gate, an OR gate, and the like, and combinational logic circuits such as a multiplexer, a flip-flop, an adder, and a counter. Cells can be implemented to realize complex IC functions. For convenience of IC design, a library including frequently used cells with their corresponding layouts are established. Therefore, when designing an IC, a designer can select desired cells from the library and place the selected cell in an automatic placement and routing block, such that a layout of the IC can be created.

It is necessary to provide contacts that bring signal outputs from cell components, or that supply power to cell components. Such contacts require an allocation of the cell's area, which increases the cell's footprint or boundary.

### SUMMARY

Embodiments of the invention provide a multi-layer integrated circuit (IC) structure that includes a cell having a cell boundary defined by a plurality of transistor-gate pitch (TGP) regions and an in-line contact region. The plurality of TGP regions include a reduced-area TGP region and non-reduced area TGP regions. The reduced-area TGP region is less than each of the non-reduced-area TGP regions. An in-line contact is within the in-line contact region and operable to electrically couple to a source or drain (S/D) region within the in-line contact region.

The above-described features in accordance with aspects of the invention provide technical effects and benefits that address the problem of increased cell footprint or cell boundary that results from providing power input contacts and output signal contacts for each cell in a cell library by reallocating the area of a given cell. More specifically the size of certain transistors and their associated pitch is reduced, and the cell area savings is reallocated to power and signal output contacts for the cell. Because the power and signal output contacts are provided within the active device pattern of the cell boundary, the power and signal output contacts are described herein as “in-line” contacts provided in an in-line contact region of the cell boundary. The tradeoff for the design in accordance with embodiments of the invention is that various performance parameters of the reduced-size transistors will be reduced in comparison to the performance parameters of the non-reduced-size transistors, however more transistors can be provided on the IC. This tradeoff is tolerable in applications where the performance parameters of the reduced-size transistors fall within a range of acceptable performance parameters for the application.

Embodiments of the invention provide a multi-layer IC structure that includes a cell having a cell boundary defined by a plurality of transistor-gate pitch (TGP) regions and an in-line contact region. The plurality of TGP regions include a reduced-area TGP region and non-reduced area TGP regions. The reduced-area TGP region is less than each of the non-reduced-area TGP regions. An in-line contact is within the in-line contact region and operable to electrically couple a power supply to a source or drain (S/D) region within the cell and outside the in-line contact region.

The above-described features in accordance with aspects of the invention provide technical effects and benefits that address the problem of increased cell footprint or cell boundary that results from providing power input contacts and output signal contacts for each cell in a cell library by reallocating the area of a given cell. More specifically the size of certain transistors and their associated pitch is reduced, and the cell area savings is reallocated to power and signal output contacts for the cell. Because the power and signal output contacts are provided within the active device pattern of the cell boundary, the power and signal output contacts are described herein as “in-line” contacts provided in an in-line contact region of the cell boundary. The tradeoff for the design in accordance with embodiments of the invention is that various performance parameters of the reduced-size transistors will be reduced in comparison to the performance parameters of the non-reduced-size transistors, however more transistors can be provided on the IC. This tradeoff is tolerable in applications where the performance parameters of the reduced-size transistors fall within a range of acceptable performance parameters for the application.

Embodiments of the invention provide a method of forming a multi-layer IC structure that includes forming a cell having a cell boundary defined by a plurality of transistor-gate pitch (TGP) regions and an in-line contact region. The plurality of TGP regions include a reduced-area TGP region and non-reduced area TGP regions. The reduced-area TGP region is less than each of the non-reduced-area TGP regions. The method further includes forming an in-line contact is within the in-line contact region and operable to electrically couple to a source or drain (S/D) region within the in-line contact region.

The above-described features in accordance with aspects of the invention provide technical effects and benefits that address the problem of increased cell footprint or cell boundary that results from providing power input contacts and output signal contacts for each cell in a cell library by reallocating the area of a given cell. More specifically the size of certain transistors and their associated pitch is reduced, and the cell area savings is reallocated to power and signal output contacts for the cell. Because the power and signal output contacts are provided within the active device pattern of the cell boundary, the power and signal output contacts are described herein as “in-line” contacts provided in an in-line contact region of the cell boundary. The tradeoff for the design in accordance with embodiments of the invention is that various performance parameters of the reduced-size transistors will be reduced in comparison to the performance parameters of the non-reduced-size transistors, however more transistors can be provided on the IC. This tradeoff is tolerable in applications where the performance parameters of the reduced-size transistors fall within a range of acceptable performance parameters for the application.

Additional technical features and benefits are realized through the techniques of the present invention. Embodiments and aspects of the invention are described in detail herein and are considered a part of the claimed subject matter. For a better understanding, refer to the detailed description and to the drawings.

### BRIEF DESCRIPTION OF THE DRAWINGS

The specifics of the exclusive rights described herein are particularly pointed out and distinctly claimed in the claims at the conclusion of the specification. The foregoing and other features and advantages of the embodiments of the invention are apparent from the following detailed description taken in conjunction with the accompanying drawings in which:

FIG. 1 depicts a three-dimensional view of a portion of an IC wafer that incorporates aspects of the invention;

FIG. 2 depicts a set of vertical transport field effect transistors (VTFETs) in accordance with aspects of the invention;

FIG. 3A depicts a frontside-down cross-sectional view of a portion of the IC wafer shown in FIG. 1 illustrating cell height, cell width, the cell area, and the cell boundary in accordance with aspects of the invention;

FIG. 3B depicts a frontside-down cross-sectional view of the portion of the IC wafer shown in FIG. 3A illustrating a CPP (contacted poly pitch) or transistor gate pitch layout in accordance with aspects of the invention;

FIG. 3C depicts a frontside-down cross-sectional view of the portion of the IC wafer shown in FIGS. 3A and 3B illustrating a CPP layout in accordance with aspects of the invention;

FIGS. 4A-4C depict a frontside-down cross-sectional view of a portion of the IC wafer shown in FIG. 1 during fabrication operations in accordance with aspects of the invention, in which:

FIG. 4A depicts a frontside-down cross-sectional view of a portion of the IC wafer shown in FIG. 1 after an initial set of fabrication operations in accordance with embodiments of the invention;

FIG. 4B depicts a frontside-down cross-sectional view of a portion of the IC wafer shown in FIG. 1 after additional fabrication operations in accordance with embodiments of the invention; and

FIG. 4C depicts a frontside-down cross-sectional view of a portion of the IC wafer shown in FIG. 1 after additional fabrication operations in accordance with embodiments of the invention;

FIG. 4D depicts a frontside-down view of selected portions of the IC wafer shown in FIG. 1 depicting an in-line contact region, a reduced VTFET region, and a non-reduced VTFET region in accordance with embodiments of the invention;

FIG. 5A depicts a cross sectional view of the portion of the IC wafer shown in FIG. 4C, taken along line Y1;

FIG. 5B depicts a cross sectional view of the portion of the IC wafer shown in FIG. 4C, taken along line X1;

FIG. 5C depicts a cross sectional view of the portion of the IC wafer shown in FIG. 4C, taken along line X2;

FIGS. 6A-6C depict a frontside-down cross-sectional view of a portion of the IC wafer shown in FIG. 1 during fabrication operations in accordance with aspects of the invention, in which:

FIG. 6A depicts a frontside-down cross-sectional view of a portion of the IC wafer shown in FIG. 1 after an initial set of fabrication operations in accordance with embodiments of the invention;

FIG. 6B depicts a frontside-down cross-sectional view of a portion of the IC wafer shown in FIG. 1 after additional fabrication operations in accordance with embodiments of the invention; and

FIG. 6C depicts a frontside-down cross-sectional view of a portion of the IC wafer shown in FIG. 1 after additional fabrication operations in accordance with embodiments of the invention;

FIG. 6D depicts a frontside-down view of selected portions of the IC wafer shown in FIG. 1 depicting an in-line power supply region, a reduced VTFET region, and a non-reduced VTFET region in accordance with embodiments of the invention; and

FIG. 7 depicts a frontside-down cross-sectional view of the portion of the IC wafer shown in FIGS. 4A-4C and/or FIGS. 6A-6C illustrating a shared in-line contact in accordance with aspects of the invention.

The diagrams depicted herein are illustrative. There can be many variations to the diagram or the operations described therein without departing from the spirit of the invention. For instance, the actions can be performed in a differing order or actions can be added, deleted or modified. Also, the term “coupled” and variations thereof describes having a communications path between two elements and does not imply a direct connection between the elements with no intervening elements/connections between them. All of these variations are considered a part of the specification.

In the accompanying figures and following detailed description of the described embodiments, the various elements illustrated in the figures are provided with two- or three-digit reference numbers. With minor exceptions, the leftmost digit(s) of each reference number correspond to the figure in which its element is first illustrated.

### DETAILED DESCRIPTION

For the sake of brevity, conventional techniques related to semiconductor device and integrated circuit (IC) fabrication may or may not be described in detail herein. Moreover, the various tasks and process steps described herein can be incorporated into a more comprehensive procedure or process having additional steps or functionality not described in detail herein. In particular, various steps in the manufacture of semiconductor devices and semiconductor-based ICs are well known and so, in the interest of brevity, many conventional steps will only be mentioned briefly herein or will be omitted entirely without providing the well-known process details.

Turning now to an overview of technologies that are more specifically relevant to aspects of the invention, semiconductor devices are used in a variety of electronic applications. ICs are typically formed from various circuit configurations of semiconductor devices (e.g., transistors, capacitors, resistors, etc.) and conductive interconnect layers (known as metallization layers) formed on semiconductor wafers. Alternatively, semiconductor devices can be formed as monolithic devices, e.g., discrete devices. Semiconductor devices and conductive interconnect layers are formed on semiconductor wafers by depositing many types of thin films of material over the semiconductor wafers, patterning the thin films, doping selective regions of the semiconductor wafers, etc.

In contemporary semiconductor fabrication processes, a large number of semiconductor devices and conductive interconnect layers are fabricated. More specifically, during the first portion of chip-making (i.e., the FEOL stage), the individual components (transistors, capacitors, etc.) are fabricated on the wafer. The MOL stage follows the FEOL stage and typically includes process flows for forming the contacts and other structures that communicatively couple to active regions (e.g., gate, source, and drain) of the device element. In the BEOL stage, these device elements are connected to each other through a network of interconnect structures to distribute signals, as well as power and ground. The conductive interconnect layers formed during the BEOL stage serve as a network of pathways that transport signals throughout an IC, thereby connecting circuit components of the IC into a functioning whole and to the outside world. Because there typically isn't enough room on the chip surface to create all of the necessary connections in a single layer, chip manufacturers build vertical levels of interconnects. While simpler ICs can have just a few metallization layers, complex ICs can have ten or more layers of wiring.

Semiconductor devices are typically formed using active regions of a wafer. In an IC having a plurality of metal oxide semiconductor field effect transistors (MOSFETs), each MOSFET has S/D regions that are formed in an active region of a semiconductor layer by incorporating n-type or p-type impurities in the layer of semiconductor material. A conventional MOSFET geometry is a non-planar FET known generally as a VTFET. VTFETs employ semiconductor fins and side-gates that can be contacted outside the active region, resulting in increased device density and some increased performance over lateral/planar devices. In VTFETs, the source-to-drain current flows in a direction that is perpendicular to a major surface of the substrate. For example, in a known VTFET configuration a major substrate surface is horizontal, and a vertical fin extends upward from the substrate surface. The fin forms the channel region of the transistor. A S/D region is situated in electrical contact with the top and bottom ends of the channel region, respectively, while a gate is disposed on one or more of the fin sidewalls.

As semiconductor industry moves towards smaller nodes, for example 7-nm node and beyond, field-effect-transistors (FETs) are aggressively scaled in order to fit into the reduced footprint or real estate, which is often dictated by the node size, with increased device density. In addition, so-called backside power distribution networks (BSPDNs) have been introduced as a means to further enhance device density. Generally, a BSPDN provides power to a mixture of signal lines and power rails in the BEOL region of the wafer, and the power rails in turn provide the power from the BSPDN to active FEOL devices such as FETs.

As previously noted herein, ICs are designed by placing various cells with different functions. For example, cells can be logic gates, such as an AND gate, an OR gate, and the like, and combinational logic circuits such as a multiplexer, a flip-flop, an adder, and a counter. Cells can be implemented to realize complex IC functions. For convenience of IC design, a library including frequently used cells with their corresponding layouts are established. Therefore, when designing an IC, a designer can select desired cells from the library and place the selected cell in an automatic placement and routing block, such that a layout of the IC can be created.

It is necessary to provide contacts that supply power to cell components, or that bring signal outputs from cell components. Such contacts require an allocation of the cell's area, which increases the cell's footprint or boundary.

Turning now to an overview of the aspects of the invention, embodiments of the invention address the problem of increased cell footprint or cell boundary that results from providing power input contacts and output signal contacts for each cell in a cell library by reallocating the area of a given cell. More specifically the size of certain transistors and their associated pitch is reduced, and the cell area savings is reallocated to power and signal output contacts for the cell. Because the power and signal output contacts are provided within the active device pattern of the cell boundary, the power and signal output contacts are described herein as “in-line” contacts provided in an in-line contact region of the cell boundary. The tradeoff for the design in accordance with embodiments of the invention is that various performance parameters of the reduced-size transistors will be reduced in comparison to the performance parameters of the non-reduced-size transistors, however more transistors can be provided on the IC. This tradeoff is tolerable in applications where the performance parameters of the reduced-size transistors fall within a range of acceptable performance parameters for the application.

In some embodiments of the in-line contact and in-line contact region can be shared across two adjacent cells. The in-line contact region can span across the adjacent cells while the in-line contact or contact system is located within the portion of the in-line contact region that is in the cell having the reduced-size active regions. Thus, the “shared” in-line contacts provide power inputs (e.g., into an adjacent top S/D region) and signal outputs (e.g., out of a bottom S/D region) for the active devices of at least two adjacent cells.

In accordance with some aspects of the invention, the cell boundary tracks the location of signal lines and power rails of the cell. In general, because of fabrication limitations, signal lines and power rails are fabricated in substantially straight lines with no irregular shapes; and the power rails, by virtue of being thicker and spaced further apart than signal lines, are typically formed at and define the cell boundary that defines the height of the cell area.

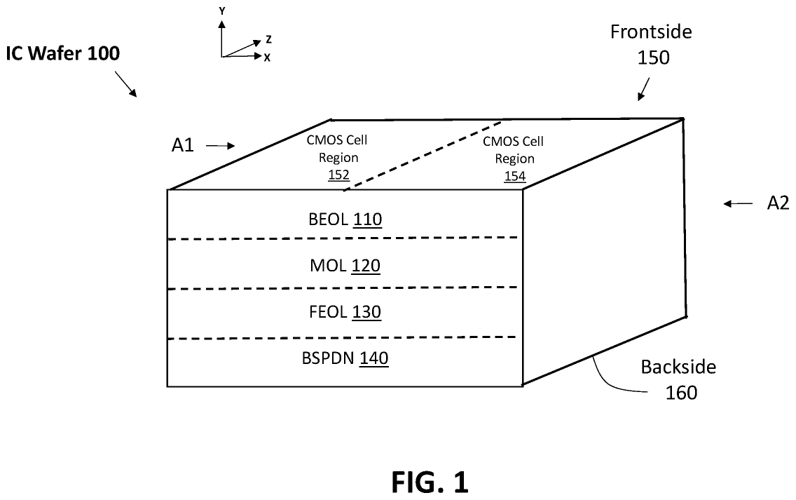

Turning now to a more detailed description of aspects of the present invention, FIG. 1 depicts a portion of an IC wafer 100 in accordance with aspects of the invention; The IC wafer 100 includes a middle-of-line (MOL) region 120 and a front-end-of-line (FEOL) region 130 positioned below a multi-layered BEOL region 110. The individual components (transistors, capacitors, etc.) and cell libraries are fabricated in the FEOL region 130. The MOL region 120 follows the FEOL region 130 and typically includes process flows for forming the contacts and other structures that communicatively couple to active regions (e.g., gate, source, and drain) of the device element. In the BEOL region 110, these device elements are connected to each other through a network of interconnect structures to distribute signals, as well as power and ground. The conductive interconnect layers formed during the BEOL region 110 serve as a network of pathways that transport signals throughout the IC wafer 100, thereby connecting circuit components of the IC wafer 100 into a functioning whole and to the outside world. Because there typically isn't enough room on the chip surface to create all of the necessary connections in a single layer, chip manufacturers build vertical levels of interconnects. While simpler IC wafers can have just a few metallization layers, complex ICs can have ten or more layers of wiring.

Interconnect structure in the BEOL region 110 that are physically close to components (e.g., transistors and the like) in the FEOL region 130 need to be small because they attach/join to the components that are themselves very small and often closely packed together. These lower-level lines, which can be referred to as local interconnects, are usually thin and short in length. Global interconnects are higher up in the structure of the IC wafer 100 and travel between different blocks of the circuit. Thus, global interconnects are typically thick, long, and more widely separated than local interconnects. Vertical connections between interconnect levels (or layers) are known as metal-filled vias and allow signals and power to be transmitted from one layer to the next. For example, a through-silicon via (TSV) is a conductive contact that passes completely through a given semiconductor wafer or die. In multi-layer IC configurations, for example, a TSV can be used to form vertical interconnections between a semiconductor device located on one layer/level of the IC and an interconnect layer located on another layer/level of the IC. These vertical interconnect structures include an appropriate metal and provide the electrical connection of the various stacked metallization layers.

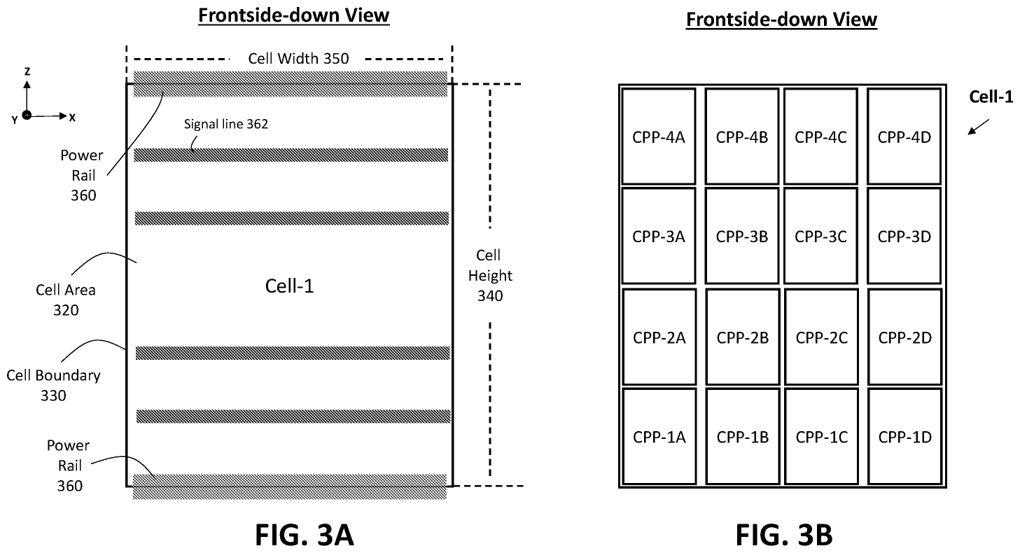

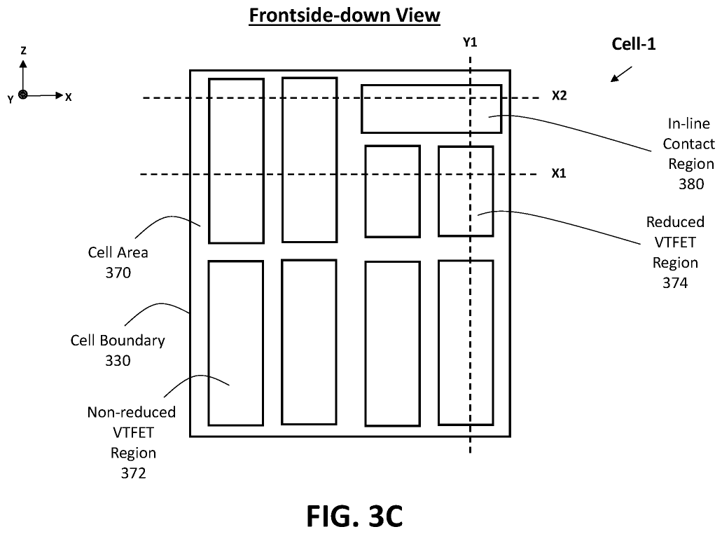

As further shown in FIG. 1, the IC wafer 100 includes a frontside 150 and a backside 160. At the backside of the wafer is a BSPDN 140. The BSPDN 140 provides power to a mixture of signal lines (e.g., signal lines 362 shown in FIG. 3A) and power rails (e.g., power rails 360 shown in FIG. 3A) in the BEOL region 110 of the wafer 100, and the power rails in turn provide the power from the BSPDN 140 to active FEOL devices in the FEOL region 130 such as FETs. The frontside 150 of the wafer 100 includes a CMOS cell region 152 and a CMOS cell region 154. In accordance with aspects of the invention, the CMOS cell regions 152, 154 include multiple cell libraries, and the cell libraries In the CMOS cell region 152 can have a different height than the cell libraries in the CMOS cell region 152. The notation A1 indicates a side view of the wafer 100 looking into the CMOS cell region 152. The notation A2 indicates a side view of the wafer 100 looking into the CMOS cell region 154.

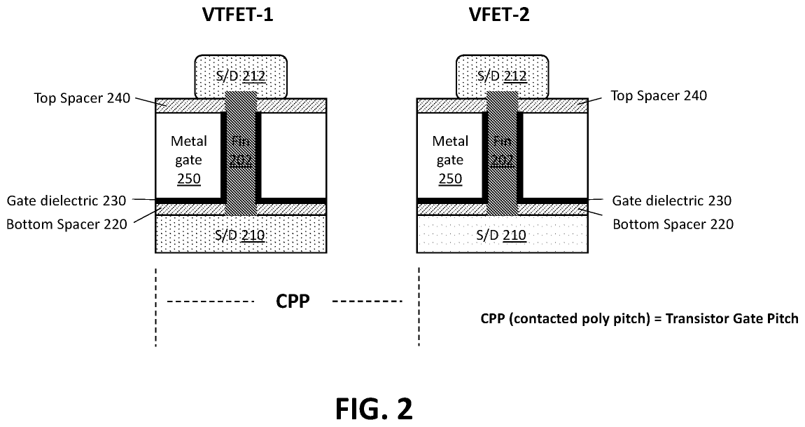

FIG. 2 depicts transistors that can be used to form the active devices of the cell regions (e.g., cell regions 152, 154 shown in FIG. 1; and/or Cell-1 shown in FIGS. 3A-3C). In FIG. 2, VTFET-1 and VTFET-2 are shown, although other suitable active devices can be used. Each of VTFET-1 and VT-FET-2 includes a bottom S/D region 210, a top S/D region 212, a channel fin 202, a gate dielectric 230, a metal gate 259, a bottom spacer 220, and a top spacer 240, configured and arranged as shown. Each of VTFET-1 and VTFET-2 employ semiconductor channel fins 202 and side-gates 259 that can be contacted outside the active region, resulting in increased device density and some increased performance over lateral/planar devices. In each of the VTFETs shown in FIG. 2, the source-to-drain current flows in a direction that is perpendicular to a major surface of the substrate (not shown). For example, in a known VTFET configuration a major substrate surface is horizontal, and a vertical fin (e.g., channel fin 202) extends upward from the substrate surface. The fin 202 forms the channel region of the transistor. S/D region 210, 212 are situated in electrical contact with the top and bottom ends of the channel fin 202, respectively, while the gate 250 is disposed on one or more sidewalls of the fins 202.

FIG. 2 also illustrates the concept of CPP. As shown, CPP is the pitch from a point on one gate of a transistor to the corresponding point on an adjacent transistor. CPP can also be represented as the transistor gate pitch (TGP).

FIG. 3A depicts a frontside-down cross-sectional view of Cell-1, which is a portion of the IC wafer 100 shown in FIG. 1. Cell-1 as shown in FIG. 3A illustrates cell height 340, cell width 350, the cell area 320, and the cell boundary 330 in accordance with aspects of the invention. In general, Cell-1's boundary 330 and area 320 are defined by the position of the power rails 360 and the signal lines 362 (only a few signal lines a 362 are shown for ease of illustration) that will be needed by the active device that make up Cell-1. The cell height 340 of a cell library can be measured by the total number of signal lines and power rails that are provided for the cell library. Each signal line 362 and each power rail 360 can be referred to as a track (T), and thus, cell height 340 can be identified by the total number of cell tracks (T) associated with the cell. A cell library that requires four (4) signal lines, ½ of a power rail at a first cell boundary, and ½ of a power rail at a second cell boundary, requires five (5) total tracks. Accordingly, such a cell library can be identified as a 5T cell.

FIG. 3B depicts another frontside-down cross-sectional view of Cell-1, which is also a portion of the IC wafer 100 shown in FIG. 1. Cell-1 as shown in FIG. 3B illustrates cell height 340, cell width 350, the cell area 320, and the cell boundary 330 in accordance with aspects of the invention as defined by the pattern of CCP that will be used for the active device of Cell-1.

FIG. 3C depicts a frontside-down cross-sectional view of Cell-1, which is also a portion of the IC wafer 100 shown in FIG. 1. Cell-1 as shown in FIG. 3C illustrates cell the cell area 320 and the cell boundary 330 after Cell-1 has been allocated to a series of long VTFET regions 372, a series of reduced-size VFET regions 374, and in-line contact region 380. By comparing Cell-1 in FIG. 3C to Cell-1 in FIG. 3B, it can be seen that providing the reduced-size VTFET regions 374 allows a portion of the cell area 370, and particularly CPP-4C and CPP4D (shown in FIG. 3B), to the in-line contact region 380 in accordance with aspects of the invention.

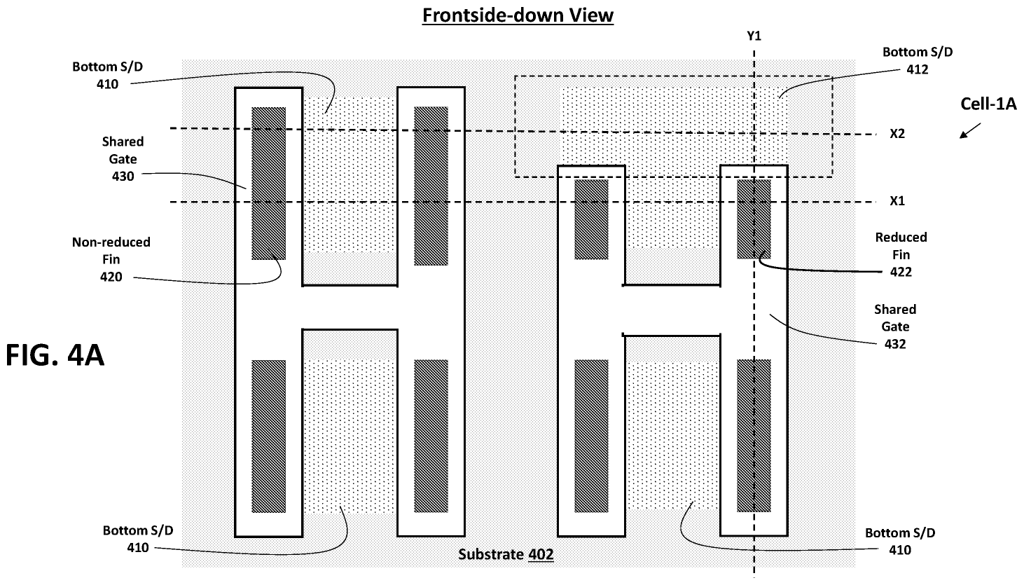

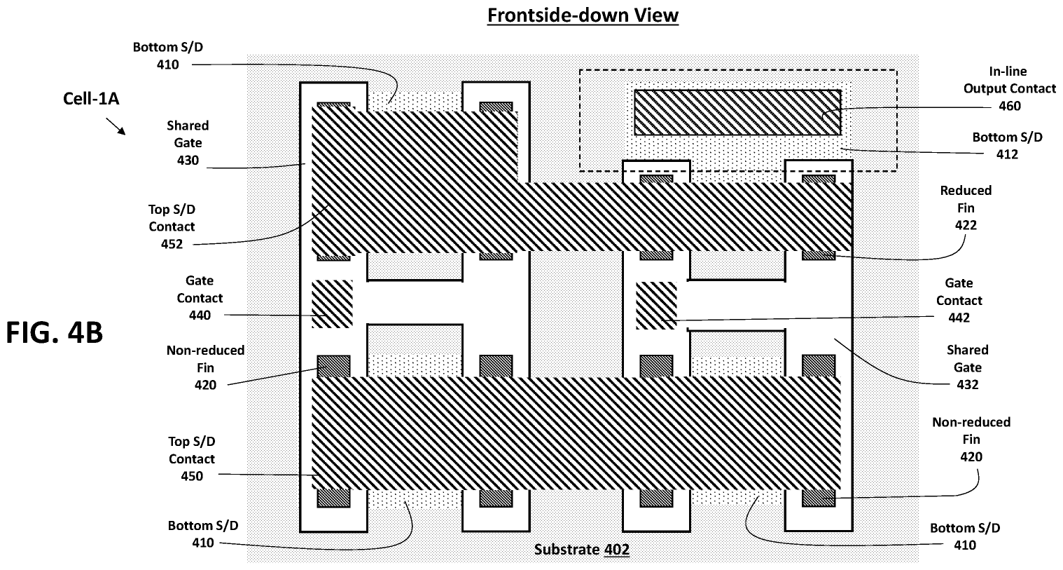

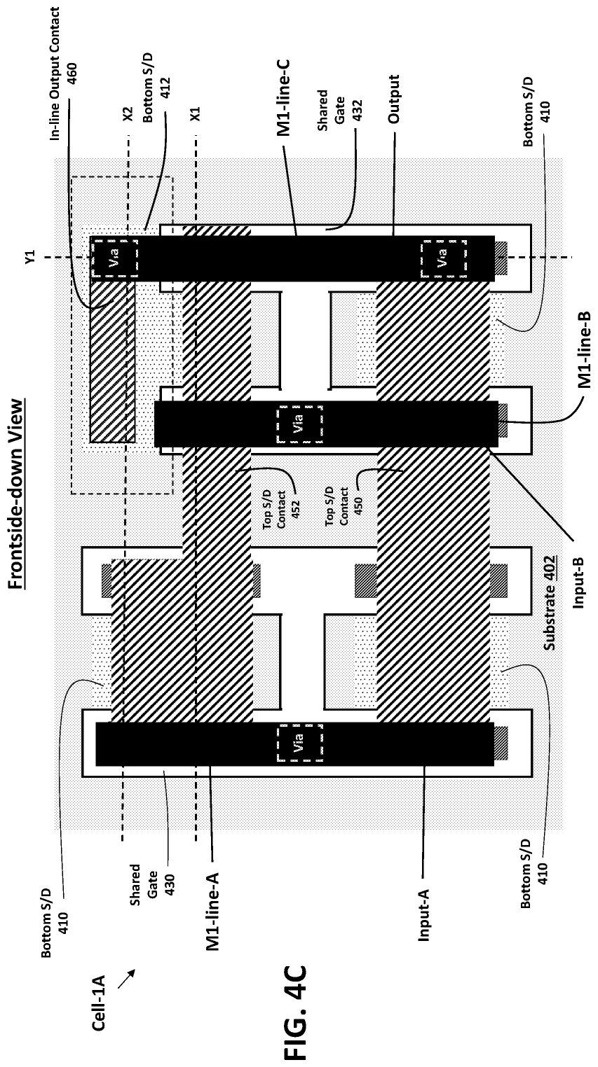

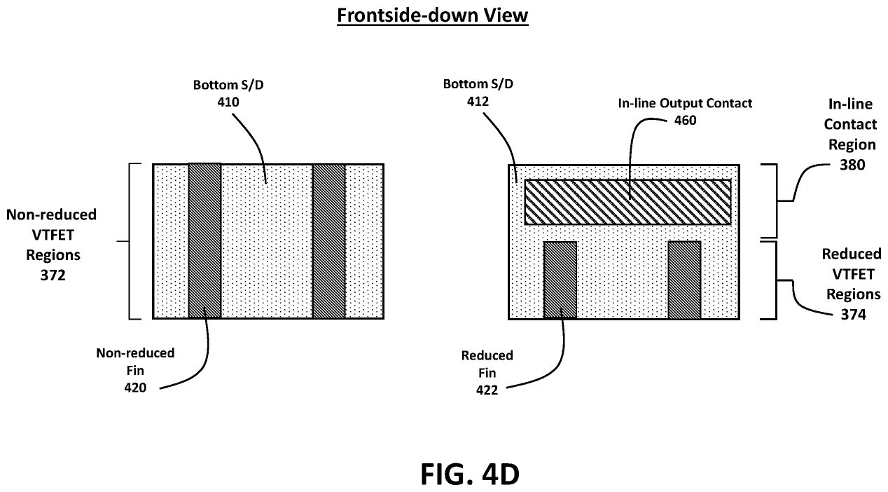

FIGS. 4A-4C depict frontside-down cross-sectional views illustrating an example of how Cell-1 shown in FIG. 3C can be configured and fabricated as Cell-1A in accordance with aspects of the invention. In the example embodiments of the invention depicted in FIGS. 4A-4C, the in-line contact region 380 is allocated to the formation of an in-line output contact 460 (shown in FIG. 4C) coupled to a bottom S/D region 412 (shown in FIG. 4C) in accordance with aspects of the invention.

As shown in FIG. 4A, known fabrication operations have been used to begin fabrication of two (2) sets of four (4) VTFETs on a substrate 402, configured and arranged as shown. As shown, the first or leftmost set of VTFETs includes bottom S/D regions 410 coupled to non-reduced-size channel fins 420. As shown, the second or rightmost set of VTFETs includes a bottom S/D region 410 coupled to non-reduced-size channel fins 420, along with a bottom S/D region 412 coupled to reduced-size channel fins 422. In accordance with aspects of the invention, a length dimension (along the Z-axis) of the non-reduced-size channel fins 420 is greater than a length dimension (along the Z-axis) of the reduced-size channel fins 422. A shared gate 430 is provided for the leftmost non-reduced-size channel fins 420; and a shared gate 432 is provided for the rightmost non-reduced-size channel fins 420 and the reduced-size fins 422. As shown, a length of a top end of the shared gate 432 is less than a length of a top end of the shared gate 430. As shown the bottom S/D region 412 extends beyond the shared gate 432 and into the in-line contact region 380 (shown in FIG. 4C). Each of the VTFETs, when fabrication is completed, can be configured to include substantially the same elements as the VTFET-1 or VTFET-2 shown in FIG. 2. In embodiments of the invention, each set the VTFETs includes an n-type VTFETs and a p-type VTFETs. Known fabrication operations have been used to fabricate Cell-1A to the stage shown in FIG. 4A. The fabrication operations for forming Cell-1A to the stage depicted in FIG. 4A are well known and so, for the sake of brevity, are not described in detail herein.

FIG. 4B depicts a frontside-down cross-sectional view of Cell-1A after additional fabrication operations in accordance with embodiments of the invention. Known fabrication operations have been used to form a top S/D region (not shown in FIG. 4B) over each of the non-reduced-size channel fins 420 and each of the reduced-size fins 422. Subsequently, known fabrication operations (e.g., damascene operations) have been used to form or deposit gate contacts 440, 442, top S/D contacts 450, 452, and an in-line output contact 460 configured and arranged as shown. In embodiments of the invention, the in-line output contact 460 includes a width dimension (extending along the Z-axis) that is less than about one TGP. Known fabrication operations have been used to fabricate Cell-1A to the stage shown in FIG. 4B. The fabrication operations for forming Cell-1A to the stage depicted in FIG. 4B are well known and so, for the sake of brevity, are not described in detail herein.

FIG. 4C depicts a frontside-down cross-sectional view of a Cell-1A after additional fabrication operations in accordance with embodiments of the invention. Known fabrication operations have been used to form lines and vias, more specifically, M1-line-A (provides Input-A) having a Via coupled to the gate contact 440 (shown in FIG. 4B); M1-line-B (provides Input-B) having a Via coupled to the gate contact 442 (shown in FIG. 4B); and M1-line-C (providing an Output) having a Via coupled to the top S/D contact 450 and a Via coupled to the in-line output contact 460. Known fabrication operations have been used to fabricate Cell-1A to the stage shown in FIG. 4C. The fabrication operations for forming Cell-1A to the stage depicted in FIG. 4C are well known and so, for the sake of brevity, are not described in detail herein.

FIG. 4D depicts a frontside-down view of selected portions of Cell-1A, depicting the components of Cell-1A that are provided in an in-line contact region 380, a reduced VTFET region 374, and a non-reduced VTFET region 372 in accordance with embodiments of the invention. As shown, in contrast to known configurations where all regions of the Cell would be allocated to portions of the VTFETs that make up the cell and additional CPPs would be required in order to access output signals from the bottom S/D regions, embodiments of the invention form reduced VTFET region(s) and use the extra space to provide the in-line contact region 380.

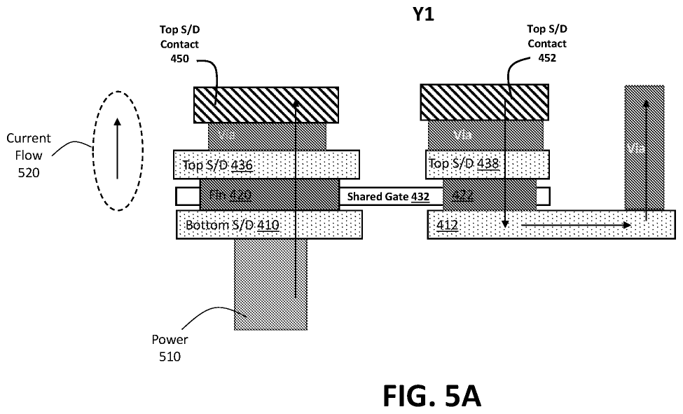

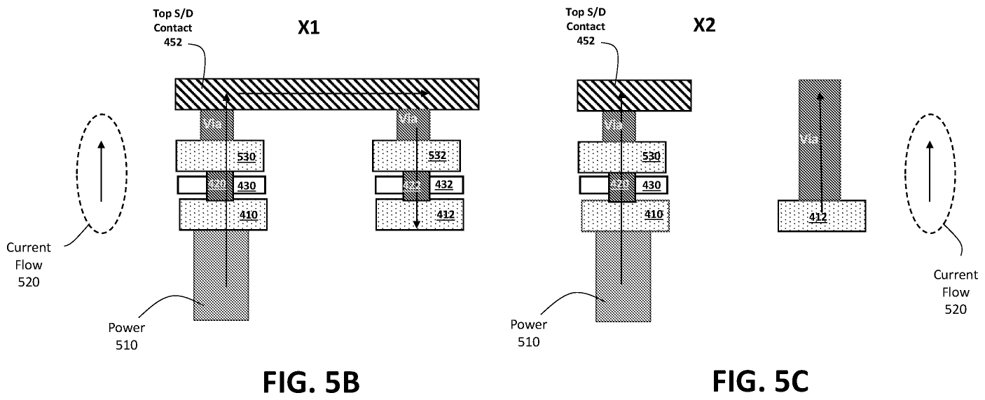

FIG. 5A depicts a cross sectional view of the Cell-1A shown in FIG. 4C, taken along line Y1, which shows a VTFET and a power source 410 in the non-reduced-size VTFET region 372; a reduced-size VTFET in the reduced-size VTFET region 374; and an extended S/D region (from the reduced-size VTFET) and a via in the in-line contact region 380. The directional arrows illustrate how signal current 520 moves from the power supply 510 through the two VFETs and the via to a contact (not shown) that would be in the in-line contact region 380.

FIG. 5B depicts a cross sectional view of Cell1-1A shown in FIG. 4C, taken along line X1, which depicts the same operations depicted in FIG. 5A but from the standpoint of the two reduced-size channel fin VTFETs positioned partially within the in-line contact region 380.

FIG. 5C depicts a cross sectional view of Cell-1A shown in FIG. 4C, taken along line X2, which depicts the same operations depicted in FIG. 5A but from the standpoint of the one VTFET positioned within the non-reduced-size VTFET region 372 and the extended bottom S/D 412 and the Via or contact 460 (shown in FIG. 4C) in the line contact region 380.

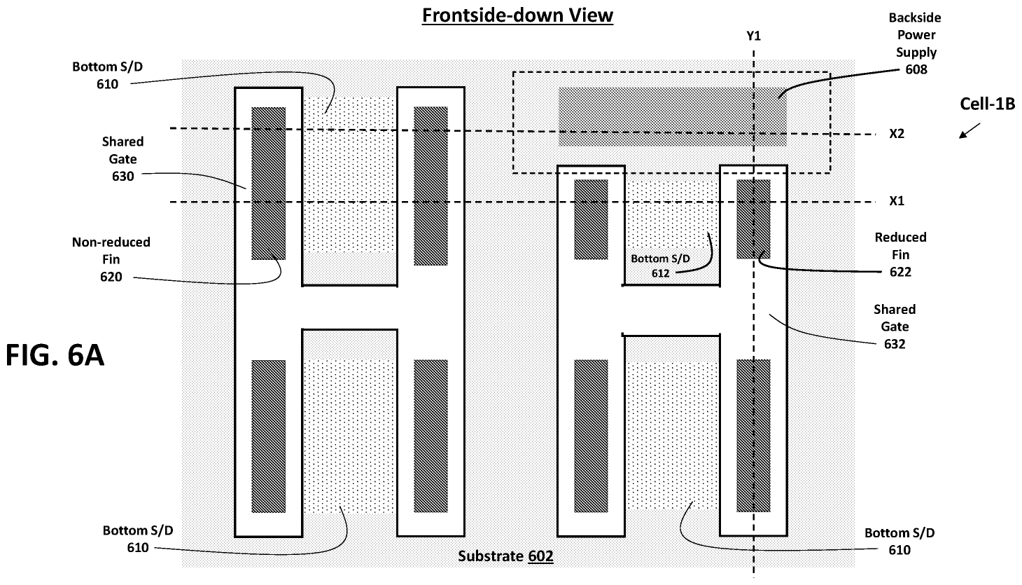

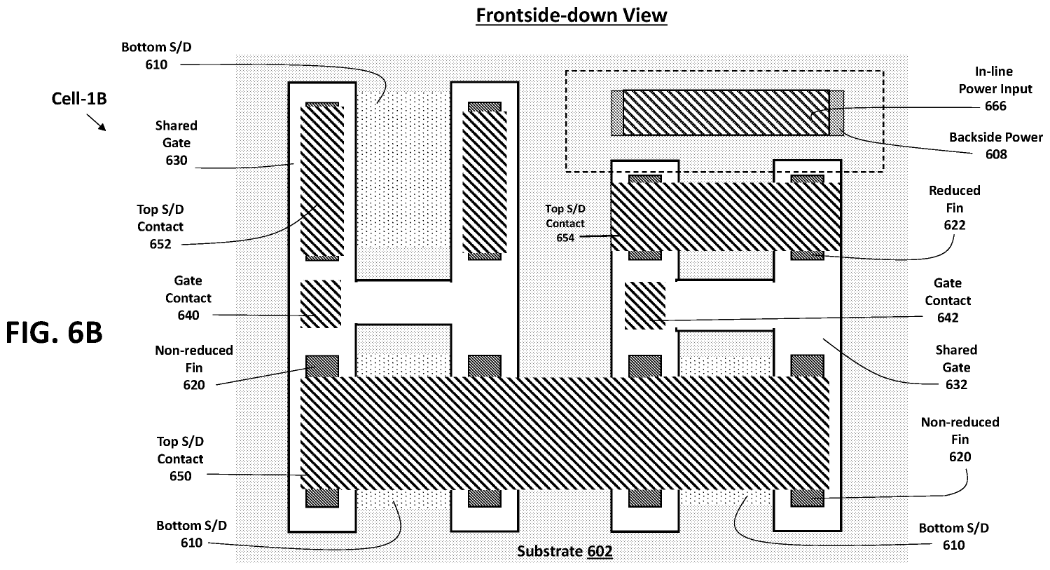

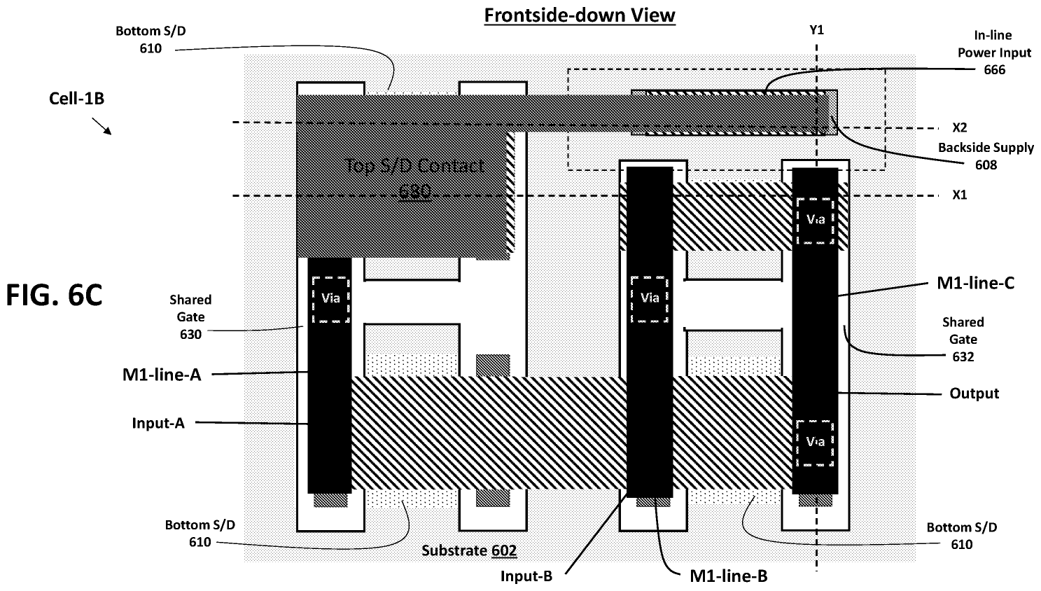

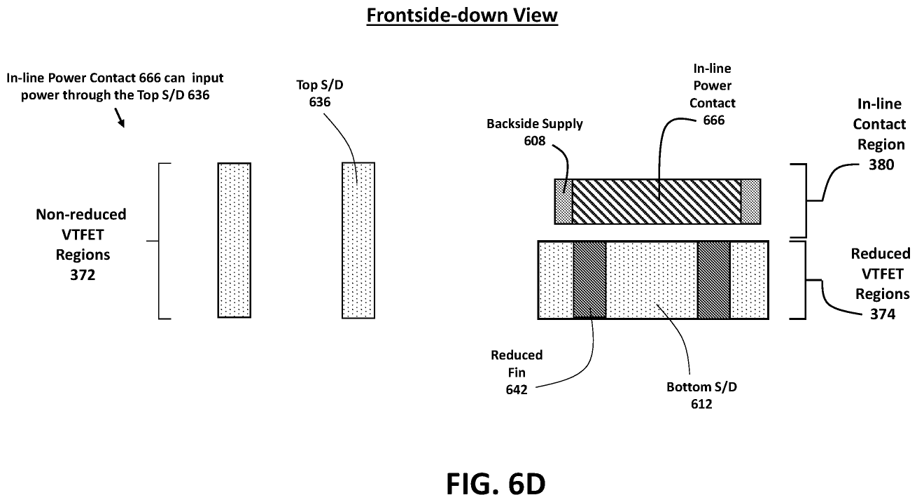

FIGS. 6A-6C depict frontside-down cross-sectional views illustrating an example of how Cell-1 shown in FIG. 3C can be configured and fabricated as Cell-1B in accordance with aspects of the invention. In the example embodiments of the invention depicted in FIGS. 6A-6C, the in-line contact region 380 is allocated to the formation of an in-line power input contact 666 (shown in FIG. 6B) coupled to a backside power supply 608 (shown in FIG. 6C) in accordance with aspects of the invention.

As shown in FIG. 6A, known fabrication operations have been used to begin fabrication of two (2) sets of four (4) VTFETs on a substrate 602, configured and arranged as shown. As shown, the first or leftmost set of VTFETs includes bottom S/D regions 610 coupled to non-reduced-size channel fins 620. As shown, the second or rightmost set of VTFETs includes a bottom S/D region 610 coupled to non-reduced-size channel fins 620, along with a bottom S/D region 612 coupled to reduced-size channel fins 622. A shared gate 630 is provided for the leftmost non-reduced-size channel fins 620; and a shared gate 632 is provided for the rightmost non-reduced-size channel fins 620 and the reduced-size fins 622. As shown, a length of a top end of the shared gate 632 is less than a length of a top end of the shared gate 630. As shown the bottom S/D region 612, in contrast to Cell-1A, does not extend beyond the shared gate 632 and into the in-line contact region 380 (shown in FIG. 3C). Each of the VTFETs, when fabrication is completed, can be configured to include substantially the same elements as the VTFET-1 or VTFET-2 shown in FIG. 2. In embodiments of the invention, each set the VTFETs includes an n-type VTFETs and a p-type VTFETs. Known fabrication operations have been used to fabricate Cell-1B to the stage shown in FIG. 6A. The fabrication operations for forming Cell-1B to the stage depicted in FIG. 6A are well known and so, for the sake of brevity, are not described in detail herein.

FIG. 6B depicts a frontside-down cross-sectional view of Cell-1B after additional fabrication operations in accordance with embodiments of the invention. Known fabrication operations have been used to form a top S/D region (not shown in FIG. 6B) over each of the non-reduced-size channel fins 620 and each of the reduced-size fins 622. Subsequently, known fabrication operations (e.g., damascene operations) have been used to form or deposit gate contacts 640, 642, top S/D contacts 650, 652, 654 and an in-line power input contact 666 configured and arranged as shown. Known fabrication operations have been used to fabricate Cell-1B to the stage shown in FIG. 6B. The fabrication operations for forming Cell-1B to the stage depicted in FIG. 6B are well known and so, for the sake of brevity, are not described in detail herein.

FIG. 6C depicts a frontside-down cross-sectional view of a Cell-1B after additional fabrication operations in accordance with embodiments of the invention. Known fabrication operations have been used to form lines and vias, more specifically, M1-line-A (provides Input-A) having a Via coupled to the gate contact 640 (shown in FIG. 6B); M1-line-B (provides Input-B) having a Via coupled to the gate contact 642 (shown in FIG. 6B); and M1-line-C (providing an Output) having a Via coupled to the top S/D contact 650 and a Via coupled to the in-line output contact 660. Known fabrication operations have been used to form top S/D contacts 680. The in-line power input is connected to adjacent top S/D region and to the power supply. The power comes up from the backside and then is connected to the top S/D of the adjacent FETs. Known fabrication operations have been used to fabricate Cell-1B to the stage shown in FIG. 6C. The fabrication operations for forming Cell-1B to the stage depicted in FIG. 6C are well known and so, for the sake of brevity, are not described in detail herein.

FIG. 6D depicts a frontside-down view of selected portions of Cell-1B, depicting the components of Cell-1B that are provided in an in-line contact region 380, a reduced VTFET region 374, and a non-reduced VTFET region 372 in accordance with embodiments of the invention. As shown, in contrast to known configurations where all regions of the Cell would be allocated to portions of the VTFETs that make up the cell and additional CPPs would be required in order to access input power signals from the backside supply 608, embodiments of the invention form reduced VTFET region(s) and use the extra space to provide the in-line contact region 380. In accordance with aspects of the invention, the in-line power contact 666 can input power through the top S/D region 636.

A configuration that is substantially similar to the configuration shown in FIGS. 5A, 5B, 5C can be provided for in-line power signal into the top S/D of a transistor adjacent to the in-line contact region 380.

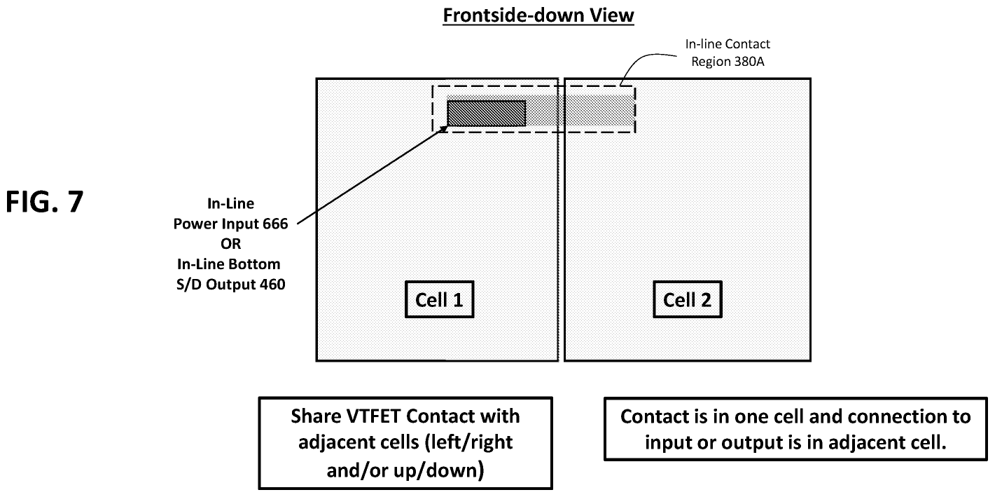

FIG. 7 depicts a frontside-down cross-sectional view of the portion of the Cells of the IC wafer 100 illustrating a shared in-line contact in accordance with aspects of the invention. FIG. 7 depicts a frontside-down cross-sectional view of the portion of the IC wafer 100 illustrating another shared in-line contact in accordance with aspects of the invention. In FIG. 7, the in-line contact and in-line contact region can be shared across two adjacent cells. The in-line contact region can span across the adjacent cells while the in-line contact or contact system is located within the portion of the in-line contact region that is in the cell having the reduced-size active regions. Thus, the “shared” in-line contacts provide power and output signal for the active devices of at least two adjacent cells.

Thus, it can be seen from the foregoing detailed description and accompanying drawings that aspects of the invention provide technical effects and benefits that address the problem of increased cell footprint or cell boundary that results from providing power input contacts and output signal contacts for each cell in a cell library by reallocating the area of a given cell. More specifically the size of certain transistors and their associated pitch is reduced, and the cell area savings is reallocated to power and signal output contacts for the cell. Because the power and signal output contacts are provided within the active device pattern of the cell boundary, the power and signal output contacts are described herein as “in-line” contacts provided in an in-line contact region of the cell boundary. The tradeoff for the design in accordance with embodiments of the invention is that various performance parameters of the reduced-size transistors will be reduced in comparison to the performance parameters of the non-reduced-size transistors, however more transistors can be provided on the IC. This tradeoff is tolerable in applications where the performance parameters of the reduced-size transistors fall within a range of acceptable performance parameters for the application.

In some embodiments of the in-line contact and in-line contact region can be shared across two adjacent cells. The in-line contact region can span across the adjacent cells while the in-line contact or contact system is located within the portion of the in-line contact region that is in the cell having the reduced-size active regions. Thus, the “shared” in-line contacts provide power inputs (e.g., into an adjacent top S/D region) and signal outputs (e.g., out of a bottom S/D region) for the active devices of at least two adjacent cells.

In accordance with some aspects of the invention, the cell boundary tracks the location of signal lines and power rails of the cell. In general, because of fabrication limitations, signal lines and power rails are fabricated in substantially straight lines with no irregular shapes; and the power rails, by virtue of being thicker and spaced further apart than signal lines, are typically formed at and define the cell boundary that defines the height of the cell area.

The methods and resulting structures described herein can be used in the fabrication of IC chips. The resulting IC chips can be distributed by the fabricator in raw wafer form (that is, as a single wafer that has multiple unpackaged chips), as a bare die, or in a packaged form. In the latter case the chip is mounted in a single chip package (such as a plastic carrier, with leads that are affixed to a motherboard or other higher-level carrier) or in a multichip package (such as a ceramic carrier that has either or both surface interconnections or buried interconnections). In any case the chip is then integrated with other chips, discrete circuit elements, and/or other signal processing devices as part of either (a) an intermediate product, such as a motherboard, or (b) an end product. The end product can be any product that includes IC chips, ranging from toys and other low-end applications to advanced computer products having a display, a keyboard or other input device, and a central processor.

Various embodiments of the present invention are described herein with reference to the related drawings. Alternative embodiments can be devised without departing from the scope of this invention. Although various connections and positional relationships (e.g., over, below, adjacent, etc.) are set forth between elements in the following description and in the drawings, persons skilled in the art will recognize that many of the positional relationships described herein are orientation-independent when the described functionality is maintained even though the orientation is changed. These connections and/or positional relationships, unless specified otherwise, can be direct or indirect, and the present invention is not intended to be limiting in this respect. Accordingly, a coupling of entities can refer to either a direct or an indirect coupling, and a positional relationship between entities can be a direct or indirect positional relationship. As an example of an indirect positional relationship, references in the present description to forming layer “A” over layer “B” include situations in which one or more intermediate layers (e.g., layer “C”) is between layer “A” and layer “B” as long as the relevant characteristics and functionalities of layer “A” and layer “B” are not substantially changed by the intermediate layer(s).

The following definitions and abbreviations are to be used for the interpretation of the claims and the specification. As used herein, the terms “comprises,” “comprising,” “includes,” “including,” “has,” “having,” “contains” or “containing,” or any other variation thereof, are intended to cover a non-exclusive inclusion. For example, a composition, a mixture, process, method, article, or apparatus that comprises a list of elements is not necessarily limited to only those elements but can include other elements not expressly listed or inherent to such composition, mixture, process, method, article, or apparatus.

Additionally, the term “exemplary” is used herein to mean “serving as an example, instance or illustration.” Any embodiment or design described herein as “exemplary” is not necessarily to be construed as preferred or advantageous over other embodiments or designs. The terms “at least one” and “one or more” are understood to include any integer number greater than or equal to one, i.e., one, two, three, four, etc. The terms “a plurality” are understood to include any integer number greater than or equal to two, i.e., two, three, four, five, etc. The term “connection” can include an indirect “connection” and a direct “connection.”

References in the specification to “one embodiment,” “an embodiment,” “an example embodiment,” etc., indicate that the embodiment described can include a particular feature, structure, or characteristic, but every embodiment may or may not include the particular feature, structure, or characteristic. Moreover, such phrases are not necessarily referring to the same embodiment. Further, when a particular feature, structure, or characteristic is described in connection with an embodiment, it is submitted that it is within the knowledge of one skilled in the art to affect such feature, structure, or characteristic in connection with other embodiments whether or not explicitly described.

For purposes of the description hereinafter, the terms “upper,” “lower,” “right,” “left,” “vertical,” “horizontal,” “top,” “bottom,” and derivatives thereof shall relate to the described structures and methods, as oriented in the drawing figures. The terms “overlying,” “atop,” “on top,” “positioned on” or “positioned atop” mean that a first element, such as a first structure, is present on a second element, such as a second structure, wherein intervening elements such as an interface structure can be present between the first element and the second element. The term “direct contact” means that a first element, such as a first structure, and a second element, such as a second structure, are connected without any intermediary conducting, insulating or semiconductor layers at the interface of the two elements.

Spatially relative terms, e.g., “beneath,” “below,” “lower,” “above,” “upper,” and the like, can be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the term “below” can encompass both an orientation of above and below. The device can be otherwise oriented (rotated 90 degrees or at other orientations) and the spatially relative descriptors used herein interpreted accordingly.

“Planarization” and “planarize” as used herein refer to a material removal process that employs at least mechanical forces, such as frictional media, to produce a substantially two-dimensional surface. A planarization process can include chemical mechanical polishing (CMP) or grinding. CMP is a material removal process that uses both chemical reactions and mechanical forces to remove material and planarize a surface.

The phrase “selective to,” such as, for example, “a first element selective to a second element,” means that the first element can be etched and the second element can act as an etch stop.

The terms “about,” “substantially,” “approximately,” and variations thereof, are intended to include the degree of error associated with measurement of the particular quantity based upon the equipment available at the time of filing the application. For example, “about” can include a range of ±8% or 5%, or 2% of a given value.

The term “conformal” (e.g., a conformal layer) means that the thickness of the layer is substantially the same on all surfaces, or that the thickness variation is less than 15% of the nominal thickness of the layer.

The terms “epitaxial growth and/or deposition” and “epitaxially formed and/or grown” mean the growth of a semiconductor material (crystalline material) on a deposition surface of another semiconductor material (crystalline material), in which the semiconductor material being grown (crystalline overlayer) has substantially the same crystalline characteristics as the semiconductor material of the deposition surface (seed material). In an epitaxial deposition process, the chemical reactants provided by the source gases can be controlled and the system parameters can be set so that the depositing atoms arrive at the deposition surface of the semiconductor substrate with sufficient energy to move about on the surface such that the depositing atoms orient themselves to the crystal arrangement of the atoms of the deposition surface. An epitaxially grown semiconductor material can have substantially the same crystalline characteristics as the deposition surface on which the epitaxially grown material is formed. For example, an epitaxially grown semiconductor material deposited on a {100} orientated crystalline surface can take on a {100} orientation. In some embodiments of the invention, epitaxial growth and/or deposition processes can be selective to forming on semiconductor surface, and cannot deposit material on exposed surfaces, such as silicon dioxide or silicon nitride surfaces.

As previously noted herein, for the sake of brevity, conventional techniques related to semiconductor device and IC fabrication may or may not be described in detail herein. By way of background, however, a more general description of the semiconductor device fabrication processes that can be utilized in implementing one or more embodiments of the present invention will now be provided. Although specific fabrication operations used in implementing one or more embodiments of the present invention can be individually known, the described combination of operations and/or resulting structures of the present invention are unique. Thus, the unique combination of the operations described in connection with the fabrication of a semiconductor device according to the present invention utilize a variety of individually known physical and chemical processes performed on a semiconductor (e.g., silicon) substrate, some of which are described in the immediately following paragraphs.

In general, the various processes used to form a micro-chip that will be packaged into an IC fall into four general categories, namely, film deposition, removal/etching, semiconductor doping and patterning/lithography. Deposition is any process that grows, coats, or otherwise transfers a material onto the wafer. Available technologies include physical vapor deposition (PVD), chemical vapor deposition (CVD), electrochemical deposition (ECD), molecular beam epitaxy (MBE) and more recently, atomic layer deposition (ALD) among others. Removal/etching is any process that removes material from the wafer. Examples include etch processes (either wet or dry), chemical-mechanical planarization (CMP), and the like. Reactive ion etching (RIE), for example, is a type of dry etching that uses chemically reactive plasma to remove a material, such as a masked pattern of semiconductor material, by exposing the material to a bombardment of ions that dislodge portions of the material from the exposed surface. The plasma is typically generated under low pressure (vacuum) by an electromagnetic field. Semiconductor doping is the modification of electrical properties by doping, for example, transistor sources and drains, generally by diffusion and/or by ion implantation. These doping processes are followed by furnace annealing or by rapid thermal annealing (RTA). Annealing serves to activate the implanted dopants. Films of both conductors (e.g., poly-silicon, aluminum, copper, etc.) and insulators (e.g., various forms of silicon dioxide, silicon nitride, etc.) are used to connect and isolate transistors and their components. Selective doping of various regions of the semiconductor substrate allows the conductivity of the substrate to be changed with the application of voltage. By creating structures of these various components, millions of transistors can be built and wired together to form the complex circuitry of a modern microelectronic device. Semiconductor lithography is the formation of three-dimensional relief images or patterns on the semiconductor substrate for subsequent transfer of the pattern to the substrate. In semiconductor lithography, the patterns are formed by a light sensitive polymer called a photo-resist. To build the complex structures that make up a transistor and the many wires that connect the millions of transistors of a circuit, lithography and etch pattern transfer steps are repeated multiple times. Each pattern being printed on the wafer is aligned to the previously formed patterns and slowly the conductors, insulators and selectively doped regions are built up to form the final device.

The flowchart and block diagrams in the Figures illustrate possible implementations of fabrication and/or operation methods according to various embodiments of the present invention. Various functions/operations of the method are represented in the flow diagram by blocks. In some alternative implementations, the functions noted in the blocks can occur out of the order noted in the Figures. For example, two blocks shown in succession can, in fact, be executed substantially concurrently, or the blocks can sometimes be executed in the reverse order, depending upon the functionality involved.

The descriptions of the various embodiments of the present invention have been presented for purposes of illustration but are not intended to be exhaustive or limited to the embodiments described. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments described herein.

What is claimed is:

1. A multi-layer integrated circuit (IC) structure comprising:
a cell comprising a cell boundary defined by a plurality of transistor-gate pitch (TGP) regions and an in-line contact region;
wherein the plurality of TGP regions comprises a reduced-area TGP region and non-reduced-area TGP regions; and
wherein the reduced-area TGP region is less than each of the non-reduced-area TGP regions; and
an in-line contact within the in-line contact region and operable to electrically couple to a source or drain (S/D) region within the in-line contact region.

2. The IC structure of claim 1 further comprising a vertical transport field effect transistor (VTFET).

3. The IC structure of claim 2 wherein the S/D region comprises a bottom S/D region of the VTFET having a first portion in the reduced-area TGP region and a second portion in the in-line contact region.

4. The IC structure of claim 2, wherein the in-line contact region is adjacent to an end region of the VTFET in the reduced-area TGP region.

5. The IC structure of claim 1, wherein the in-line contact region is adjacent at least one of the non-reduced-area TGP regions.

6. The IC structure of claim 1, wherein the in-line contact comprises a width dimension that is less than about one TGP.

7. The IC structure of claim 2, wherein the VTFET is electrically connect to a backside power supply.

8. The IC structure of claim 2, wherein the in-line contact is operable to pass an output signal from the VTFET.

9. The IC structure of claim 1 further comprising a first fin in the reduced-area TGP region and a second fin in at least one of the non-reduced-area TGP regions, wherein a length dimension of the first fin is less than a length dimension of the second fin.

10. The IC structure of claim 1, wherein the in-line contact is electrically connected to a metal wiring layer above the in-line contact.

11. A multi-layer integrated circuit (IC) structure comprising:
a cell comprising a cell boundary defined by a plurality of transistor-gate pitch (TGP) regions and an in-line contact region;
wherein the plurality of TGP regions comprises a reduced-area TGP region and non-reduced-area TGP regions; and
wherein the reduced-area TGP region is less than each of the non-reduced-area TGP regions; and
an in-line contact within the in-line contact region and operable to electrically couple a power supply to a source or drain (S/D) region within the cell and outside the in-line contact region.

12. The IC structure of claim 11 further comprising a vertical transport field effect transistor (VTFET).

13. The IC structure of claim 12 wherein the S/D region comprise a top S/D region of the VTFET, wherein top S/D region is within the cell, outside the in-line contact region, and connected by a contact to the in-line contact region.

14. The IC structure of claim 13, wherein the top S/D region of the VTFET is within at least one of the non-reduced-area TGP regions.

15. The IC structure of claim 11, wherein the in-line contact region is adjacent the reduced-area TGP region.

16. The IC structure of claim 11, wherein the in-line contact region is adjacent at least one of the non-reduced-area TGP regions.

17. The IC structure of claim 11 further comprising a first fin in the reduced-area TGP region and a second fin in at least one of the non-reduced-area TGP regions, wherein a length dimension of the first fin is less than a length dimension of the second fin.

18. The IC structure of claim 11, wherein the power supply comprises a backside power supply.

19. The IC structure of claim 11, wherein the in-line contact comprises a width dimension that is less than about one TGP.

20. A method of forming a multi-layer integrated circuit (IC) structure comprising:
forming a cell comprising a cell boundary defined by a plurality of transistor-gate pitch (TGP) regions and an in-line contact region;
wherein the plurality of TGP regions comprises a reduced-area TGP region and non-reduced-area TGP regions; and
wherein the reduced-area TGP region is less than each of the non-reduced-area TGP regions; and
forming an in-line contact within the in-line contact region and operable to electrically couple to a source or drain (S/D) region within the in-line contact region.
